(19) United States
(12) Patent Application Publication
(10) Pub. No.: US 2026/0101505 A1
(43) Pub. Date: Apr. 9, 2026

(54) FLASH MEMORY DEVICE AND METHOD FOR FORMING THE SAME

(71) Applicant: Winbond Electronics Corp., Taichung CIty (TW)

(72) Inventor: Han-Huei HSU, Changhua County (TW)

(21) Appl. No.: 19/053,719

(22) Filed: Feb. 14, 2025

(30) Foreign Application Priority Data
Oct. 4, 2024 (TW) 113137858

(51) Int. Cl. H10B 41/30; H10D 30/01; H10D 30/68; H10D 62/10; H10D 64/01

(52) U.S. Cl. CPC H10B 41/30; H10D 30/0411; H10D 30/6891; H10D 62/117; H10D 64/035

(57) ABSTRACT

A flash memory device and a method for forming the same are provided. The method includes providing a substrate. The method further includes forming a tunneling dielectric layer on the substrate and stacked structures on the tunneling dielectric layer. Each of the stacked structures includes a floating gate and a mask pattern. The method further includes performing a first etching process to form first trenches in the substrate and performing a second etching process to remove a portion of the substrate exposed from the first trenches to form second trenches. The method further includes entirely forming a dielectric material filling the second trenches and covering the stacked structures. The method further includes removing the mask pattern and the dielectric material on a first top surface and a first side surface of each of the floating gates. The remaining dielectric material forms isolation features in the second trenches.

### CROSS REFERENCE TO RELATED APPLICATIONS

This Application claims priority of Taiwan Patent Application No. 113137858, filed on Oct. 4, 2024, the entirety of which is incorporated by reference herein.

### BACKGROUND OF THE INVENTION

### Field Of The Invention

The present invention relates to a flash memory device and a method for forming a flash memory device, and in particular, it is related to an isolation feature of a NOR flash memory device and a method for forming an isolation feature of a NOR flash memory device.

### Description of the Related Art

In a NOR flash memory, the scaling-down of memory cells creates a bottleneck because of the problems that can occur when the gate length and the gate width are decreased. For example, the process of forming self-aligned floating gates or control gates may form voids or seams due to poor gap filling, leading to electrical and reliability issues. Therefore, a novel flash memory and a method for forming the same are needed to solve the aforementioned problems.

### BRIEF SUMMARY OF THE INVENTION

An embodiment of the invention provides a method for forming a flash memory device. The method includes providing a substrate, forming a tunneling dielectric layer on the substrate, forming stacked structures on the tunneling dielectric layer. Each of the stacked structures includes a floating gate and a mask pattern located on the floating gate. The method further includes performing a first etching process to form first trenches in the substrate, performing a second etching process to remove a portion of the substrate exposed from the first trenches to form second trenches in the substrate, entirely forming a dielectric material. The dielectric material fills the second trenches and covers the stacked structures. The method further includes removing the mask pattern and the dielectric material on a first top surface and a first side surface of each of the floating gates. The remaining dielectric material forms isolation features in the second trenches.

An embodiment of the invention provides a flash memory device. The flash memory device includes a substrate, a tunneling dielectric pattern, a floating gate, insulating spacers and isolation features. The substrate has a mesa. The mesa has a first top surface and first side surfaces connected to the first top surface. The tunneling dielectric pattern is disposed on the first top surface of the mesa. The floating gate is disposed on the tunneling dielectric pattern. The floating gate has a second bottom surface in contact with the tunneling dielectric pattern and second side surfaces connected to the second bottom surface. The insulating spacers are disposed on portions of the second side surfaces of the floating gate close to the second bottom surface. The isolation features are disposed on the first side surfaces of the mesa. The third top surfaces of the insulating spacers are coplanar with fourth top surfaces of the isolation feature. The third top surface and the fourth top surfaces are higher than the second bottom surface of the floating gate.

### BRIEF DESCRIPTION OF THE DRAWINGS

The present invention can be more fully understood by reading the subsequent detailed description and examples with references made to the accompanying drawings, wherein:

FIGS. 1 to 9 are perspective schematic views of intermediate stages of a method for forming a flash memory device in accordance with some embodiments of the invention.

### DETAILED DESCRIPTION OF THE INVENTION

The following description is made for the purpose of illustrating the general principles of the invention and should not be taken in a limiting sense. The scope of the invention is best determined by reference to the appended claims.

In the fabrication process of a NOR flash memory, shallow trench isolation features are formed in the substrate first. The shallow trench isolation features have tops protruding from the substrate. Next, a pull back process is performed to enlarge the gaps between the tops of the shallow trench isolation features to form spaces for accommodating floating gates. The floating gates are formed in a self-aligned manner in the spaces using a deposition process and a subsequent planarization process. Next, the tops of the shallow trench isolation features are removed to form spaces between the floating gates to accommodate a gate dielectric layer and a control gate. Next, the gate dielectric layer and the control gate are formed on the floating gates to form a flash memory. However, the size and the shape of bottom corners of the floating gate are defined by the tops of the shallow trench isolation features after performing the pull back process. During the formation of the floating gate, voids or seam may be formed in the floating gate due to poor gap filling. Furthermore, since the pull back process will isotropically remove portions of the tops of the shallow trench isolation features, the self-aligned floating gate will have rounded bottom corners. Tapered gaps having narrow tops and wide bottoms will be formed between the floating gates having rounded corners. During the formation of the control gate, voids or seams will also be formed in the control gate due to poor gap filling, thereby affecting the electrical performances and reliability of the resulting flash memory devices. Therefore, a novel flash memory and a method for forming the same are desirable to solve the aforementioned problems.

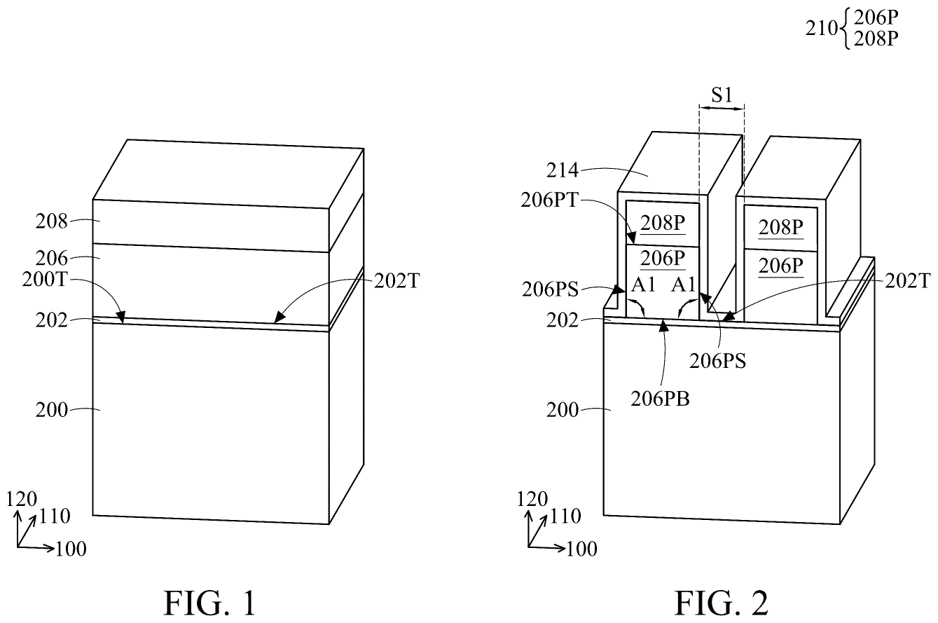

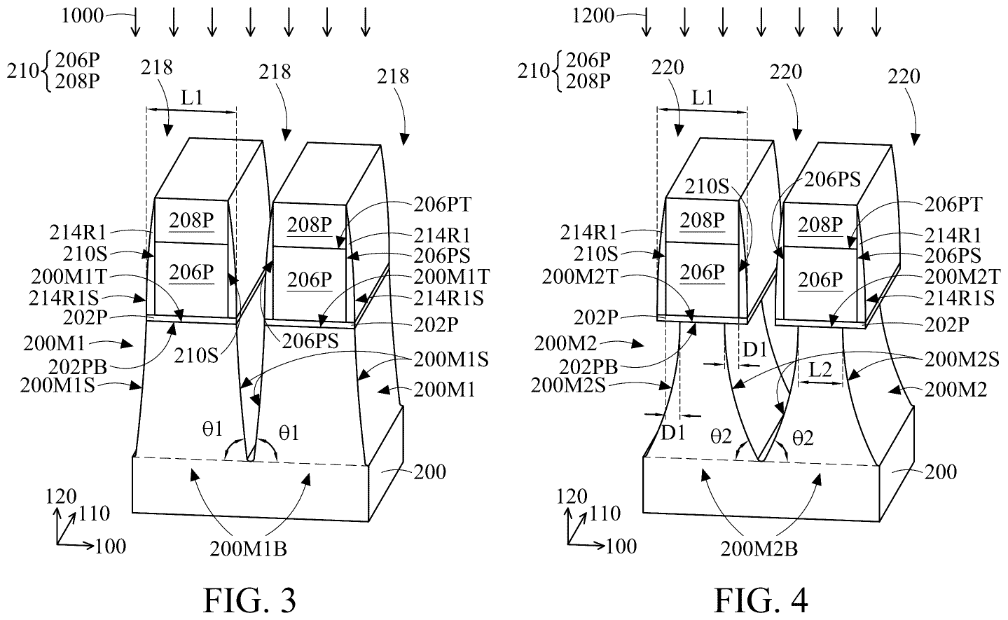

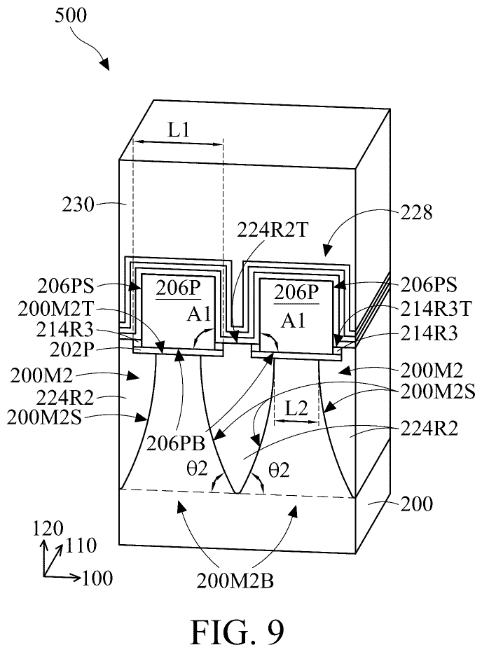

FIGS. 1 to 9 are perspective views of each process stage of the method for forming a flash memory device 500 such as a NOR flash memory device in accordance with some embodiments of the disclosure. In FIG. 1 and subsequent figures, directions 100, 110 and 120 are shown as x, y and z directions respectively. The directions 100 and 110 are directions substantially parallel to the top surface 200T of the substrate 200 (FIG. 1). In addition, the directions 100 and 110 are respectively the width direction and the length direction of the flash memory device 500. The direction 120 is a direction substantially perpendicular to the top surface 200T of the substrate 200 (also referred to as the longitudinal direction 120). In the method for forming the flash memory device 500, a stacked structure 210 including a floating gate 206P is first formed using the processes shown in FIGS. 1 and 2. The stacked structure 210 is used as an etching mask for the subsequent formation of an isolation feature 224R2. Next, the isolation feature 224R2 of the flash memory device 500 is formed using the processes shown in FIGS. 3 to 7. Next, a gate dielectric layer 228 and a control gate layer 230 of the flash memory device 500 are formed using the processes shown in FIGS. 8 and 9. The flash memory device 500 shown in FIG. 9 is formed.

As shown in FIG. 1, a substrate 200 is provided. The semiconductor substrate 200 may be an elemental semiconductor substrate, such as a silicon substrate or a germanium substrate; or a compound semiconductor substrate, such as a silicon carbide substrate or a gallium arsenide substrate. The semiconductor substrate 200 may be a silicon-on-insulator substrate. The substrate 200 may be a silicon substrate.

A thermal oxidation or a chemical vapor deposition process is performed to entirely form a tunneling dielectric layer 202 on a top surface 200T of the substrate 200. The tunneling dielectric layer 202 is silicon oxide.

Several deposition processes are then performed to sequentially and entirely form a floating gate layer 206 and a mask layer 208 on a top surface 202T of the tunneling dielectric layer 202. The floating gate layer 206 fully covers the tunneling dielectric layer 202. The mask layer 208 fully covers the floating gate layer 206. The floating gate layer 206 is, for example, polysilicon. The mask layer 208 is, for example, silicon oxide, silicon nitride, silicon oxynitride, titanium nitride, photoresist or other suitable mask materials.

As shown in FIG. 2, a photolithography process and a subsequent anisotropic etching process are performed to form a mask pattern (not shown) on the mask layer 208. Next, the mask layer 208 and the floating gate layer 206 are patterned sequentially until the tunneling dielectric layer 202 is exposed to form the stacked structures 210 spaced apart from each other on the tunneling dielectric layer 202. The stacked structures 210 are used to define the formation positions of the isolation features 224R2 of the flash memory device 500, and allow a portion of the top surface 202T of the tunneling dielectric layer 202 to be exposed from between the stacked structures 210. The stacked structure 210 includes a floating gate 206P and a mask pattern 208P located on the floating gate 206P. The patterning process that forms stacked structure 210 defines the final shape and size of the floating gate 206P of the flash memory device 500. As shown in FIG. 2, the cross-sectional shape of the floating gate 206P may be rectangular. Each of the floating gates 206P has a bottom surface 206PB close to the substrate 200, a top surface 206PT away from the substrate 200, and opposite side surfaces 206PS connecting the bottom surface 206PB and the top surface 206PT. Since the floating gate 206P of the stacked structure 210 is formed by a photolithography process and an anisotropic etching process, a bottom corner A1 formed by the bottom surface 206PB and the side surface 206PS of the floating gate 206P is a sharp corner rather than a rounded corner. Moreover, a spacing S1 between the floating gates 206P is uniform near the top surfaces 206PT or the bottom surfaces 206PB of them. There is no tapered spacing S1 having a narrow top and a wide bottom formed between the floating gates 206P.

After the stacked structure 210 is formed, a low-temperature deposition process such as an atomic layer deposition is performed to conformally form an insulating liner 214 on the stacked structure 210 and on the top surface 202T of the tunneling dielectric layer 202 that is not covered by the stacked structure 210. The insulating liner 214 may be used to protect the opposite side surfaces 206PS of the floating gate 206P in order to prevent the floating gate 206P from being damaged during the subsequent etching process of forming the isolation feature 224R2. The insulating liner 214 and the mask pattern 208P may have the same material, such as silicon oxide.

As shown in FIG. 3, an etching process 1000 such as an anisotropic etching process is performed to remove a portion of the tunneling dielectric layer 202 (FIG. 2) that is not covered by the stacked structure 210 and a portion of the substrate 200 using the stacked structure 210 as an etching mask. The etching process 1000 will remove a portion of the insulating liner 214 on the top surface 210T of the stacked structure 210 and on the top surface 202T of the tunneling dielectric layer 202 between the stacked structures 210. After the etching process 1000 is performed, a plurality of trenches 218 and a plurality of mesas 200M1 sandwiched between the trenches 218 are formed in the substrate 200. The remaining tunneling dielectric layer 202 forms a plurality of tunneling dielectric patterns 202P on the substrate 200. In addition, the remaining insulating liner layer 214 forms a plurality of insulating spacers 214R1 in a self-aligned manner on the opposite side surfaces 210S of the stacked structure 210. The insulating spacers 214R1 and the floating gate 206P cover different portions of the tunneling dielectric pattern 202P.

As shown in FIG. 3, each of the mesa 200M1 has a top surface 200M1T and opposite side surfaces 200M1S connected to the top surface 200M1T. A plurality of outer side surfaces 214R1S of the insulating spacer 214R1 are aligned with the corresponding side surfaces 200M1S of the mesa 200M1. Moreover, a bottom surface 202PB of each of the tunneling dielectric patterns 202P is fully covered by the corresponding mesa 200M1. In the direction 100, the top surface 200M1T of the mesa 200M1 and the bottom surface 202PB of the tunneling dielectric pattern 202P may have the same lateral dimension L1.

As shown in FIG. 3, an angle θ1 is formed between a portion of the side surface 200M1S close to the bottom 200M1B of the mesa 200M1 (adjacent to the bottom 218B of the trench 218) and a direction substantially parallel to the top surface 200M1T of the mesa 200M1. The angle θ1 is an acute angle close to 90 degrees. For example, the angle θ1 may be between about 82 degrees and about 88 degrees.

The etching process 1000 is a selective etching process. Since the substrate 200 formed of, for example, silicon has a higher etching selectivity relative to the insulating liner 214 and the mask pattern 208P formed of, for example, silicon oxide, no damage will be caused to the top surface 206 PT and the side surfaces 206PS of the floating gate 206P after the trench 218 is formed.

As shown in FIG. 4, an isotropic etching process 1200 is performed to remove a portion of the substrate 200 exposed from the trench 218 using the stacked structure 210 and the insulating spacer 214R1 as an etching mask, so that the horizontal and vertical dimensions of the trench are enlarged along the direction 100 and the direction substantially perpendicular to the top surface 200M1T of the mesa 200M1. After the etching process 1000 is performed, a plurality of trenches 220 and a plurality of mesas 200M2 sandwiched between the trenches 220 are formed in the substrate 200.

Each of the mesa 200M2 has a top surface 200M2T and opposite side surfaces 200M2S connected to the top surface 200M2T. As shown in FIG. 4, the top surface 200M2T of the mesa 200M2 has a lateral dimension L2 in the direction 100. The lateral dimension L1 of the bottom surface 202PB of the tunneling dielectric pattern 202P is greater than the lateral dimension L2. Therefore, after the etching process 1200 is performed, the tunneling dielectric pattern 202P fully covers the top surface 200M2T of the corresponding mesa 200M2. In addition, a portion of the bottom surface 202PB of each of the tunneling dielectric patterns 202P is exposed from the corresponding mesa 200M2. In the direction 100, the distances D1 between the opposite side surfaces 200M2S of the mesa 200M2 and the corresponding side surface 210S of the stacked structure 210 may be the same.

Compared to the mesa 200M1, the mesa 200M2 may have a tapered cross-sectional profile. As shown in FIG. 4, an angle θ2 is formed between a portion of the side surface 200M2S close to the bottom 200M2B of the mesa 200M2 (adjacent to the bottom 220B of the trench 220) and a direction substantially parallel to the top surface 200M2T. The angle θ2 is smaller than the angle θ1. For example, the angle θ2 may be less than or equal to 75 degrees.

The etching process 1200 is a selective etching process. Since the substrate 200 formed of, for example, silicon has a higher etching selectivity relative to the insulating liner 214 and the mask pattern 208P formed of, for example, silicon oxide, no damage will be caused to the top surface 206 PT and side surfaces 206PS of the floating gate 206P after the trench 220 is formed.

The etching process 1000 and the etching process 1200 may be performed sequentially in the same etching machine. Therefore, the etching processes 1000 and 1200 may be in-situ etching processes. After the etching process 1000 and the etching process 1200 are performed, the floating gate 206P and the mesa 200M2 thereunder may have a hammer-shaped cross-sectional profile.

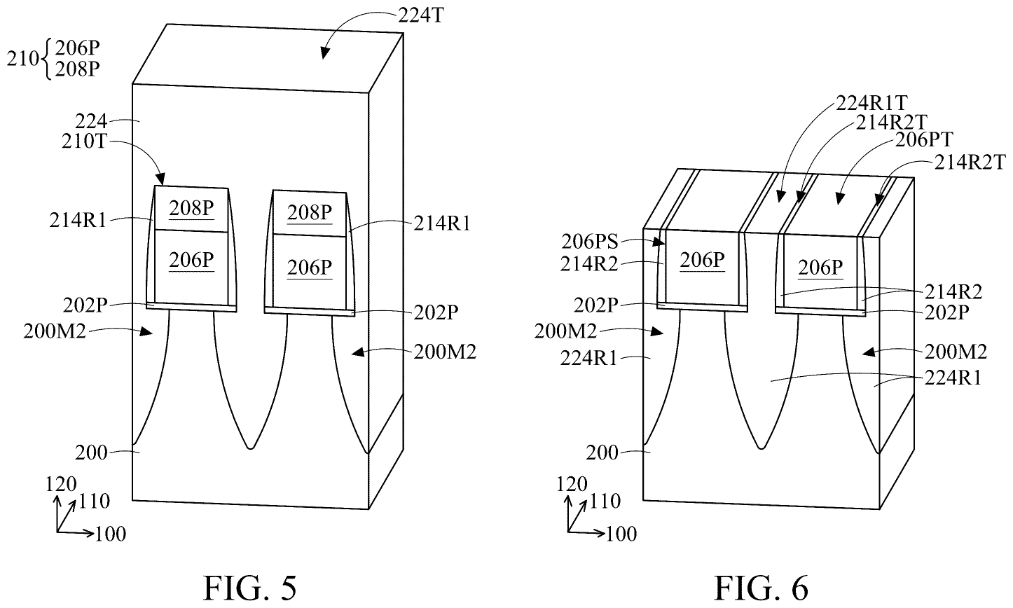

Next, as shown in FIG. 5, a deposition process is performed to entirely form a dielectric material 224. The dielectric material 224 fills the trenches 220 and the spaces between the stacked structures 210. In addition, the dielectric material 224 covers the stacked structures 210 and the insulating spacers 214R1. A top surface 224T of the dielectric material 224 is higher than the top surface 210T of the stacked structure 210 and is substantially a planar surface. The dielectric material 224 includes, for example, silicon oxide (SiO), silicon nitride (SiN), silicon oxynitride (SiON), and/or a combination thereof. After the dielectric material 224 such as spin-on glass is formed, an annealing process may be performed to remove the solvent in the spin-on glass and convert it into a solid silicon oxide dielectric material.

Next, as shown in FIG. 6, a planarization process such as chemical mechanical polishing is performed to remove a portion of the dielectric material 224 and a portion of the mask pattern 208P on the top surface 206 PT of the floating gate 206P until the top surface 206 PT of the floating gate 206P is exposed. Therefore, a dielectric material 224R1 in the trench 220 and between the floating gates 206P is formed. In addition, insulating spacers 214R2 are formed on the opposite side surfaces 206PS of the floating gate 206P. After the planarization process is performed, the top surface 206 PT of the floating gate 206P may be flush with (coplanar with) the top surface 224R1T of the dielectric material 224R1 and the top surfaces 214R2T of the insulating spacers 214R2.

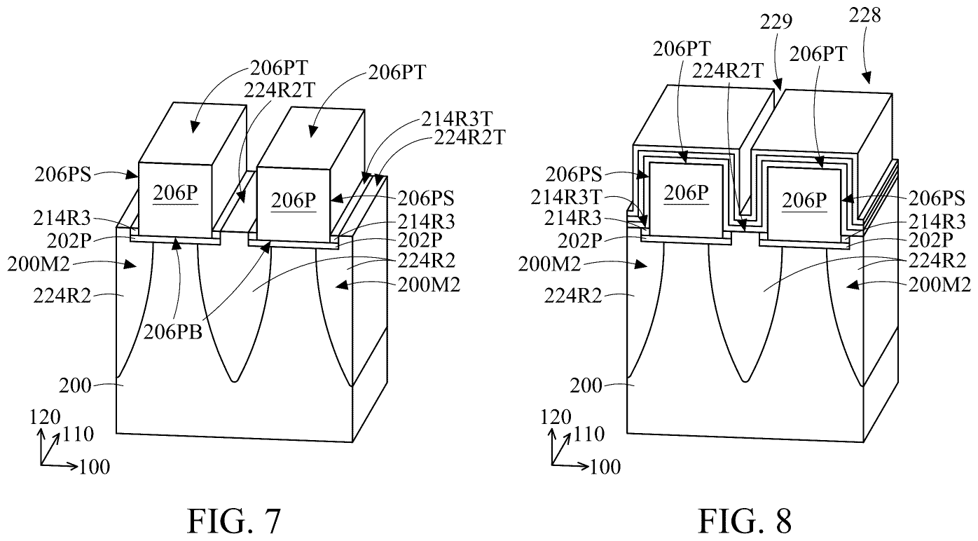

As shown in FIG. 7, the dielectric material 224R1 and the insulating spacers 214R2 are recessed from the top surface 206 PT of the floating gate 206P. A cleaning process such as wet chemical is performed to remove a portion of the dielectric material 224R1 on the side surfaces 206PS of the floating gate 206P. The cleaning process partially removes the dielectric material 224R1 between the floating gates 206P and the insulating spacers 214R2 (FIG. 6), so that the remaining insulating spacers 214R3 formed from the insulating spacers 214R2 partially covers the side surfaces 206PS of the floating gate 206P. The insulating spacers 214R3 cover the lower portions of the side surfaces 206PS of the floating gate 206P, leaving upper portions of the side surfaces 206PS of the floating gate 206P exposed. At this time, the tunneling dielectric pattern 202P is still fully covered by the floating gate 206P and the insulating spacers 214R3. The remaining dielectric material forms a plurality of isolation features 2 24R2 in the trenches 220. The isolation feature 2 24R2 is separated from the floating gate 206P by the insulating spacer 214R3 and tunneling dielectric pattern 202P. A top surface 224R2T of the isolation feature 224R2 is substantially flush with (coplanar with) a top surface 214R3T of the insulating spacer 214R3 and is located above the bottom surface 206PB of the floating gate 206P in the direction 120. Compared to the top surface 206 PT of the floating gate 206P, the top surface 224R2T of the isolation feature 224R2 and the top surface 214R3T of the insulating spacer 214R3 are closer to the bottom surface 206PB of the floating gate 206P. The isolation feature 224R2 is, for example, a shallow trench isolation feature.

As shown in FIG. 8, a deposition process such as chemical vapor deposition or atomic layer deposition is performed to conformally form a gate dielectric layer 228 on the isolation feature 224R2, the insulating spacers 214R3, and the top surface 206 PT and portions of the side surfaces 206PS of the floating gate 206P. The gate dielectric layer 228 may cover the top surface 224R2T of the isolation feature 224R2 and the top surface 214R3T of the insulating spacer 214R3 without filling the gap 229 between the floating gates 206P. The gate dielectric layer 228 is not contact with the mesa 200M2. The gate dielectric layer 228 includes silicon oxide, silicon nitride, silicon oxynitride, or a triple-layer structure including silicon oxide/silicon nitride/silicon oxide (ONO).

As shown in FIG. 9, a deposition process is performed such as chemical vapor deposition to form a control gate layer 230 on the gate dielectric layer 228. The control gate layer 230 fills the gap 229 between the floating gates 206P. After performing the aforementioned processes, the flash memory device 500 is formed. The control gate layer 230 includes a layer of polysilicon or other conductive material.

As shown in FIG. 9, the flash memory device 500 includes the substrate 200, the tunneling dielectric pattern 202P, the floating gate 206P, the insulating spacers 214R3 and the isolation features 224R2. The substrate 200 has the mesa 200M2. The mesa 200M2 has the top surface 200M2T and the side surfaces 200M2S connected to the top surface 200M2T. The tunneling dielectric pattern 202P is disposed on the top surface 200M2T of the mesa 200M2. The floating gate 206P is disposed on the tunneling dielectric pattern 202P. The floating gate 206P has the bottom surface 206PB in contact with the tunneling dielectric pattern 202P and the side surfaces 206PS connected to bottom surface 206PB. The insulating spacers 214R3 are disposed on portions of the side surfaces 206PS of the floating gate 206P close to the bottom surface 206PB. The isolation features 2 24R2 are disposed on the side surfaces 200M2S of the mesa 200M2. The top surfaces 214R3T of the insulating spacers 214R3 are coplanar with the top surfaces 224R2T of the isolation features 224R2. Furthermore, the top surface 214R3T of the insulating spacer 214R3 and the top surface 224R2T of the isolation feature 2 24R2 are higher than the bottom surface 206PB of the floating gate 206P. The bottom surface 206PB and the side surfaces 206PS of the floating gate 206P form sharp-angled bottom corners A1. The angle θ2 between the side surface 200M2S close to the bottom 200M2B of the mesa 200M2 (adjacent to the bottom 220B of the trench 220) and the direction 100 substantially parallel to the top surface 200M2T is less than or equal to 75 degrees. The lateral dimension L2 of the top surface 200M2T of the mesa 200M2 is smaller than the lateral dimension L1 of the bottom surface 206PB of the floating gate 206P. The flash memory device 500 further includes a gate dielectric layer 228 and a control gate layer 230. The gate dielectric layer 228 is formed on the isolation features 2 24R2 and the floating gate 206P. The control gate layer 230 is formed on the gate dielectric layer 228.

The method for forming the flash memory device of the disclosure uses a deposition process and a subsequent patterning process to form a stacked structure of the floating gate to serve as an etching mask for shallow trench isolation features. The floating gate is formed before the formation of the shallow trench isolation feature. The process steps can be saved. In addition, voids or seams caused by poor gate material filling formed during the formation of the self-aligned floating gate in the conventional processes can be avoided. The method for forming the flash memory device may use an in-situ isotropic etching process to define the shape of the trench for the shallow trench isolation feature. Therefore, the floating gate and the mesa thereunder may together have a hammer-shaped cross-section profile. The cross-sectional shape of the floating gate formed by the anisotropic etching process is rectangular, and the bottom corners of the floating gate are sharp corners rather than rounded corners. There is no tapered gap having a narrow top and a wide bottom formed between the floating gates. When the control gate layer is formed in the gap between the floating gates, voids or seams caused by poorly filled gate material can be avoided. The electrical performance and reliability of the flash memory device can be improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a flash memory device, comprising:
provide a substrate;
forming a tunneling dielectric layer on the substrate;
forming stacked structures on the tunneling dielectric layer, wherein each of the stacked structures comprises a floating gate and a mask pattern located on the floating gate;
performing a first etching process to form first trenches in the substrate;
performing a second etching process to remove a portion of the substrate exposed from the first trenches to form second trenches in the substrate;
entirely forming a dielectric material, wherein the dielectric material fills the second trenches and covers the stacked structures; and
removing the mask pattern and the dielectric material on a first top surface and a first side surface of each of the floating gates, wherein the remaining dielectric material forms isolation features in the second trenches.

2. The method for forming a flash memory device according to claim 1, wherein forming the stacked structures comprises:
forming a floating gate layer and a mask layer sequentially on the tunneling dielectric layer; and
patterning the floating gate layer and the mask layer until the tunneling dielectric layer is exposed.

3. The method for forming a flash memory device as claimed in claim 1, wherein a first bottom surface of each of the floating gates close to the substrate and the first side surface of each of the floating gates form a sharp angle after forming the stacked structures.

4. The method for forming a flash memory device as claimed in claim 1, wherein the first etching process is an anisotropic etching process, and the second etching process is an isotropic etching process.

5. The method for forming a flash memory device as claimed in claim 1, further comprising:
forming an insulating liner on the stacked structures before performing the first etching process, wherein
the remaining tunneling dielectric layer forms tunneling dielectric patterns on the substrate, and the remaining insulating liner layer forms insulating spacers on opposite side surfaces of each of the stacked structures after performing the first etching process.

6. The method for forming a flash memory device as claimed in claim 5, wherein first mesas are formed in the substrate and sandwiched between the first trenches after performing the first etching process, wherein each of the first mesas has a second top surface and second side surfaces connected to the second top surface, and wherein outer side surfaces of the insulating spacers are aligned with the second side surfaces of the corresponding first mesa.

7. The method for forming a flash memory device as claimed in claim 6, wherein a third bottom surface of each of the tunneling dielectric patterns is fully covered by the corresponding first mesa.

8. The method for forming a flash memory device as claimed in claim 7, wherein second mesas are formed in the substrate and sandwiched between the second trenches after performing the second etching process, wherein each of the second mesas has a fourth top surface and fourth side surfaces connected to the fourth top surface, and wherein the second top surface has a first lateral dimension, the fourth top surface has a second lateral dimension, and the first lateral dimension is greater than the second lateral dimension.

9. The method for forming a flash memory device as claimed in claim 8, wherein a portion of the third bottom surface of each of the tunneling dielectric patterns is exposed from the corresponding second mesa after performing the second etching process, and the second lateral dimension is less than a third lateral dimension of the third bottom surface.

10. The method for forming a flash memory device as claimed in claim 8, wherein a first acute angle formed between the second side surface of the first mesa positioned close to a second bottom of each of the first mesa and a first direction substantially parallel to the second top surface is greater than a second acute angle formed between the fourth side surface of the second mesa positioned close to a fourth bottom of the second mesa and the first direction.

11. The method for forming a flash memory device as claimed in claim 5, wherein removing the mask pattern and the dielectric material on the first top surface and the first side surface of each of the floating gates comprises:
performing a planarization process to remove the dielectric material and the mask patterns on the first top surfaces of the floating gates; and
performing a cleaning process to partially remove the dielectric material and the insulating spacers between the floating gates, so that the remaining insulating spacers partially cover the first side surfaces of the floating gates.

12. The method for forming a flash memory device as claimed in claim 11, wherein fifth top surfaces of the remaining insulating spacers are coplanar with sixth top surfaces of the isolation features, and the fifth top surfaces and the sixth top surfaces are located above a first bottom surface of each of the floating gates positioned close to the substrate.

13. The method for forming a flash memory device as claimed in claim 12, further comprising:
conformally forming a gate dielectric layer on the floating gates; and
forming a control gate layer on the gate dielectric layer.

14. The method for forming a flash memory device as claimed in claim 13, wherein the gate dielectric layer covers the fifth top surfaces and the sixth top surfaces.

15. The method for forming a flash memory device as claimed in claim 13, wherein the control gate layer fills gaps between the floating gates.

16. A flash memory device, comprising:
a substrate, wherein the substrate has a mesa, the mesa has a first top surface and first side surfaces connected to the first top surface;
a tunneling dielectric pattern disposed on the first top surface of the mesa;
a floating gate disposed on the tunneling dielectric pattern, wherein the floating gate has a second bottom surface in contact with the tunneling dielectric pattern and second side surfaces connected to the second bottom surface;
insulating spacers disposed on portions of the second side surfaces of the floating gate close to the second bottom surface; and
isolation features disposed on the first side surfaces of the mesa, wherein third top surfaces of the insulating spacers are coplanar with fourth top surfaces of the isolation features, and wherein the third top surface and the fourth top surfaces are higher than the second bottom surface of the floating gate.

17. The flash memory device of claim 16, wherein the second bottom surface and the second side surfaces of the floating gate form sharp angles.

18. The flash memory device of claim 16, wherein an angle between each of the first side surfaces positioned close to a first bottom of each of the mesas and a first direction substantially parallel to the first top surface is less than or equal to 75 degrees.

19. The flash memory device of claim 16, wherein a first lateral dimension of the first top surface is smaller than a second lateral dimension of the second bottom surface.

20. The flash memory device of claim 16, further comprising:
a gate dielectric layer formed on the isolation features and the floating gate; and
a control gate layer formed on the gate dielectric layer.
